(19) United States
(12) Patent Application Publication
(10) Pub. No.: US 2010/0156474 A1
(43) Pub. Date: Jun. 24, 2010

(54) GATE DRIVE CIRCUIT AND DISPLAY APPARATUS HAVING THE SAME

(76) Inventors: Kyung-Ho Park, Cheonan-si (KR); Seong-Young Lee, Anyang-si (KR)

Correspondence Address: F. CHAU & ASSOCIATES, LLC, 130 WOODBURY ROAD, WOODBURY, NY, 11797, US

(21) Appl. No.: 12/481,295

(22) Filed: Jun. 9, 2009

(30) Foreign Application Priority Data
Dec. 24, 2008 (KR) 2008-133763

(51) Int. Cl. H03K 3/00

(52) U.S. Cl. 327/108

(57) ABSTRACT

A gate drive circuit includes m stages cascade connected to one another, each stage respectively outputting one of a plurality of gate signals. An m-th stage includes a pull-up part, a pull-down part, a boost-up part, a first maintenance part and a second maintenance part. The pull-up part outputs a high voltage of a first clock signal at the high voltage of an m-th gate signal. The pull-down part applies a low voltage to an output node of the pull-up part. The boost-up part boosts a voltage charged by an offset second clock signal. The first maintenance part maintains the first node at a low voltage in response to the boosted voltage of the second node. In addition, the second maintenance part maintains the m-th gate signal at the low voltage in response to the high voltage of the first clock signal.

### CROSS-REFERENCE TO RELATED APPLICATIONS

This application claims priority under 35 U.S.C. §119 to Korean Patent Application No. 2008-133763, filed on Dec. 24, 2008 in the Korean Intellectual Property Office (KIPO), the disclosure of which is incorporated by reference in its entirety herein.

### BACKGROUND OF THE INVENTION

1. Technical Field

Exemplary embodiments of the present invention relate to a gate drive circuit and a display apparatus having the gate drive circuit. More particularly, exemplary embodiments of the present invention relate to a gate drive circuit for reducing high-temperature noise and a display apparatus having the gate drive circuit.

2. Discussion of Related Art

Amorphous silicon gate (ASG) technology was developed to reduce manufacturing costs of a panel module for a display apparatus and to reduce the total size of the display apparatus. In ASG, a gate drive circuit is disposed in a peripheral area of a panel and a switching element is disposed in a display area of the panel.

Since a clock signal is generated by selectively outputting a clock signal having a continuously changing phase, ASG generates noise when the display apparatus is not driven. Various structures have been proposed to minimize the noise generated when the display apparatus is not driven.

However, the proposed structures cannot effectively control the noise generated when the temperature of the gate driving part increases beyond a certain threshold amount (e.g., when the gate driving part is driven for an extended amount of time). As a result, the noise of the gate signal may reduce the display quality of the display apparatus.

Thus, there is a need for a gate drive circuit that can reduce high-temperature noise and a display apparatus having the gate drive circuit.

### SUMMARY OF THE INVENTION

According to an exemplary embodiment of the present invention, a gate drive circuit includes a plurality of stages cascade connected to one another. Each of the stage respectively output one of a plurality of gate signals. An m-th stage includes a pull-up part, a pull-down part, a boost-up part, a first maintenance part and a second maintenance part. The pull-up part outputs a high voltage of a first clock signal as a high voltage of an m-th gate signal in response to the high voltage of a first node. The pull-down part applies a low voltage to an output node of the pull-up part in response to a high voltage of an (m+1)-th gate signal. The boost-up part boosts a voltage charged by a second clock signal that has a phase that is offset from the first clock signal to apply the boosted voltage to a second node. The first maintenance part maintains a voltage potential of the first node at a low voltage, in response to the boosted voltage of the second node. In addition, the second maintenance part maintains the m-th gate signal at the low voltage in response to the high voltage of the first clock signal, where m is a natural number.

According to an exemplary embodiment of the present invention, a display apparatus includes a display panel, a source driving circuit and a gate driving circuit. The display panel includes a display area having a plurality of gate lines and a plurality of source lines and a peripheral area surrounding the display area. The display area is configured to display an image. The source drive circuit outputs a plurality of data signals to the source lines. The gate drive circuit is integrated in the peripheral area. The gate drive circuit includes a plurality of stages, each stage outputting one of a plurality of gate signals to the gate lines, respectively. An m-th stage includes a pull-up part, a pull-down part, a boost-up part, a first maintenance part and a second maintenance part. The pull-up part outputs a high voltage of a first clock signal as the high voltage of an m-th gate signal in response to the high voltage of a first node. The pull-down part applies a low voltage to an output node of the pull-up part in response to a high voltage of an (m+1)-th gate signal. The boost-up part boosts a voltage charged by a second clock signal having a phase that is offset with respect to the first clock signal to apply the boosted voltage to a second node in response to the clock signal. The first maintenance part maintains a voltage potential of the first node at the low voltage in response to the boosted voltage of the second node. The second maintenance part maintains the m-th gate signal at the low voltage, in response to the high voltage of the first clock signal. The gate lines may cross the source lines and m is a natural number.

### BRIEF DESCRIPTION OF THE DRAWINGS

The present invention will become more apparent by describing in detailed exemplary embodiments thereof with reference to the accompanying drawings, in which:

FIG. 1 is a plan view illustrating a display apparatus according to an exemplary embodiment of the present invention;

FIG. 2 is a block diagram illustrating a gate drive circuit of FIG. 1 according to an exemplary embodiment of the present invention;

FIG. 3 is a circuit diagram illustrating a stage of FIG. 2 according to an exemplary embodiment of the present invention;

FIG. 4 illustrates waveform diagrams showing exemplary input/output signals of the gate drive circuit of FIG. 3;

FIG. 5 is a graph illustrating exemplary current-voltage characteristics of a first maintenance part of FIG. 3;

FIG. 6 illustrates exemplary waveform diagrams showing a gate signal according to threshold voltages of the first maintenance part of FIG. 3;

FIG. 7 is a block diagram illustrating a gate drive circuit according to an exemplary embodiment of the present invention; and

FIG. 8 illustrates waveform diagrams showing exemplary input/output signals of the gate drive circuit of FIG. 7.

### DETAILED DESCRIPTION OF EXEMPLARY EMBODIMENTS

The present invention is described more fully hereinafter with reference to the accompanying drawings, in which exemplary embodiments of the present invention are shown. The present invention may, however, be embodied in many different forms and should not be construed as limited to the exemplary embodiments set forth herein.

It will be understood that when an element or layer is referred to as being “on,” “connected to” or “coupled to” another element or layer, it can be directly on, connected or coupled to the other element or layer or intervening elements or layers may be present. Like numerals refer to like elements throughout. Hereinafter, exemplary embodiments of the present invention will be explained in detail with reference to the accompanying drawings.

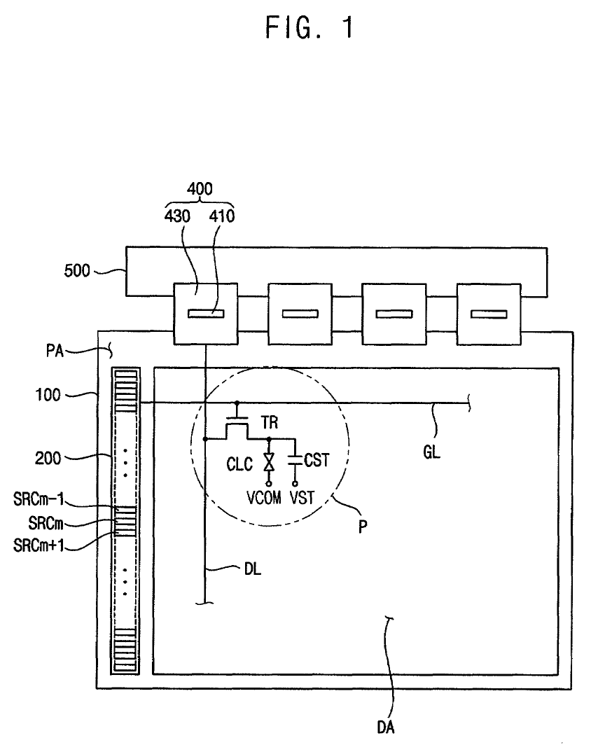

FIG. 1 is a plan view illustrating a display apparatus according to an exemplary embodiment of the present invention. Referring to FIG. 1, the display apparatus includes a display panel 100, a gate drive circuit 200, a source drive circuit 400, and a printed circuit board (PCB) 500.

The display panel 100 includes a display area DA and a peripheral area PA surrounding the display area DA. The display area DA includes gate lines, source lines, and a plurality of pixel parts. Each pixel part P includes a thin-film transistor (TFT) electrically connected to a gate line GL and a source line DL, a liquid crystal capacitor CLC electrically connected to the TFT, and a storage capacitor CST connected to the liquid crystal capacitor CLC.

The gate drive circuit 200 includes a shift register sequentially outputting gate signals of a high level to the gate lines GL. The shift register includes a plurality of stages SRCm−1, SRCm and SRCm+1 (e.g., m is a natural number). The gate drive circuit 200 may be integrated in the peripheral area PA at one end of the gate lines GL.

The source drive circuit 400 includes a source drive chip 410 outputting data signals to the source lines DL, and a flexible printed circuit board (FPCB) 430 including the source drive chip 410 and electrically connecting the PCB 500 and the display panel 100. The mounting of the source drive chip 410 on the FPCB 430 is merely an example, as the source drive chip 410 may be directly mounted on the display panel 100. For example, the source drive chip 410 may be directly integrated in the peripheral area PA of the display panel 100.

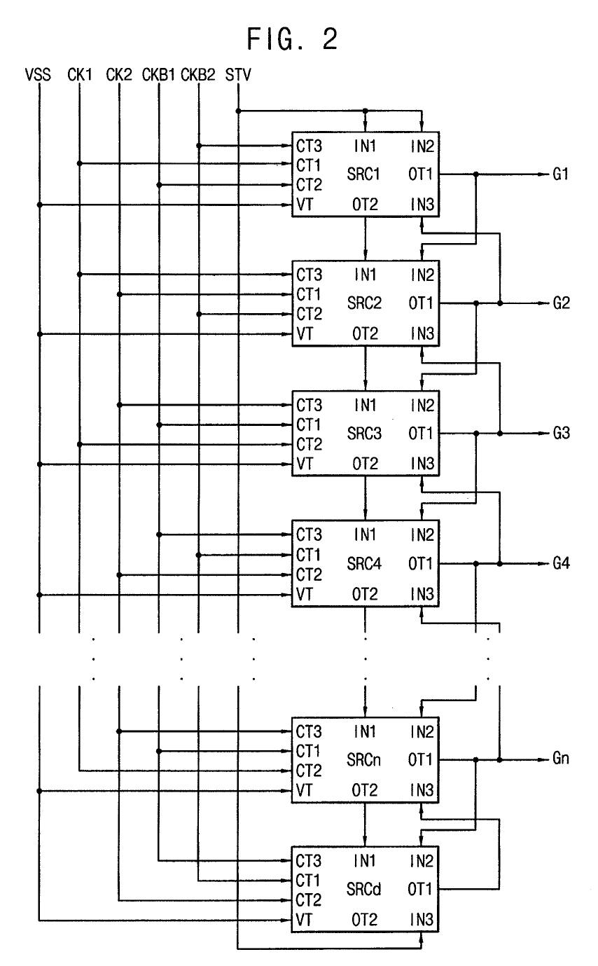

FIG. 2 is a block diagram illustrating a gate drive circuit of FIG. 1 according to an exemplary embodiment of the present invention. Referring to FIGS. 1 and 2, the gate drive circuit 200 includes a first stage SRC1 to a n-th stage SRCn dependently connected to each other (e.g., cascade connected), and a dummy stage SRCd.

The first stage SRC1 to the n-th stage SRCn are connected to the n gate lines, respectively, to sequentially output the n gate signals to the gate lines GL. The dummy stage SRCd controls driving of the n-th stage SRCn. The dummy stage SRCd is not directly connected to the gate lines GL. For example, output terminals of stages SRC1-SRCN are connected to the gate lines GL, while an output terminal of the dummy stage SRCd is connected to an input terminal of stage SRCN.

Each stage includes a first clock terminal CT1, a second clock terminal CT2, a third clock terminal CT3, a first input terminal IN1, a second input terminal IN2, a third input terminal IN3, a voltage terminal VT, a first output terminal OT1, and a second output terminal OT2.

The first clock terminal CT1 receives a first clock signal CK1, a second clock signal CK2, a first inverted clock signal CKB1, or a second inverted clock signal CKB2. The clock signals CK1, CK2, CKB1 and CKB2 include a high voltage VDD and a low voltage VSS, and may have a 2H pulse width and a 4H period, where, “H” denotes a horizontal period.

A phase of the second clock signal CK2 is delayed by 1H with respect to a phase of the first clock signal CK1 where, “1H” represents one horizontal period. A phase of the first inverted clock signal CKB1 is opposite to the phase of the first clock signal CK1, and is delayed by 1H with respect to the phase of the second clock signal CK2. A phase of the second inverted clock signal CKB2 is opposite to the phase of the clock signal CK2, and is delayed by 1H with respect to the phase of the first inverted clock signal CKB1.

For example, the first clock terminal CT1 of a (4K-3)-th stage (e.g., SRC1) receives the first clock signal CK1, the first clock terminal CT1 of a (4K-2)-th stage (e.g., SRC2) receives the second clock signal CK2, the first clock terminal CT1 of a (4K-1)-th stage (e.g., SRC3) receives the first inverted clock signal CKB1, and the first clock terminal CT1 of a 4K-th stage (e.g., SRC4) receives the second inverted clock signal CKB2, where K is a natural number.

The second clock terminal CT2 receives an inverted clock signal having a phase opposite to the phase of a clock signal received by the first clock terminal CT1. For example, the second clock terminal CT2 of the (4K-3)-th stage SRC1 (e.g., K is a natural number) receives the first inverted clock signal CKB1, the second clock terminal CT2 of the (4K-2)-th stage SRC2 receives the second inverted clock signal CKB2, the second clock terminal CT2 of the (4K-i)-th stage SRC3 receives the first clock signal CK1, and the second clock terminal CT2 of the 4K-th stage SRC4 receives the second clock signal CK2.

The third clock terminal CT3 receives a clock signal having a phase advanced (or offset) by 1H with respect to a phase of the clock signal received by the first clock terminal CT1. Namely, the phase of the clock signal received by the third clock terminal CT3 is delayed by 1H with respect to the phase of the clock signal received by the first clock terminal CT1.

For example, the third clock terminal CT3 of the (4K-3)-th stage SRC1 (e.g., K is a natural number) receives the second inverted clock signal CKB2 having a phase offset by 1H with respect to the phase of the first clock signal CK1, the third clock terminal CT3 of the (4K-2)-th stage SRC2 receives the first clock signal CK1 that is offset by 1H with respect to a phase of the second clock signal CK2, the third clock terminal CT3 of the (4K-1)-th stage SRC3 receives the second clock signal CK2 that is offset by 1H with respect to a phase of the first inverted clock signal CKB1, and the third clock terminal CT3 of the 4K-th stage SRC4 receives the first inverted clock signal CKB1 that is offset by 1H with respect to a phase of the second inverted clock signal CKB2.

The first input terminal IN1 receives a vertical start signal STV or a carry signal of a previous stage. For example, the first input terminal IN1 of the first stage SRC1 receives the vertical start signal STV, and the first input terminal IN1 of the second stage SRC2 to the dummy stage SRCd receives the carry signal of the previous stages SRC1 to SRCn, respectively.

The second input terminal IN2 receives the vertical start signal STV or a gate signal, e.g., the output signal of the previous stage. For example, the second input terminal IN2 of the first stage SRC1 receives the vertical start signal STV, and the first input terminals IN1 of the second stage SRC2 to the dummy stage SRCd1 receive the gate signal G1, G2, G3, . . . , Gn outputted from the previous stage SRC1 to SRCn.

The third input terminal IN3 receives a gate signal, e.g., the output signal of a next stage or the vertical start signal STV. For example, the second input terminals IN3 of the first stage SRC1 to the n-th stage SRCn receive the gate signal G1, G2, G3, . . . , Gn of the next stages, and the third input terminal of the dummy stage SRCd receives the vertical start signal STV. The vertical signal STV received by the third input terminal IN3 of the dummy stage SRCd may be a vertical start signal corresponding to a next frame.

The voltage terminals VT receive the low voltage VSS. The first output terminals OT1 of stages SRC1-SRCn are electrically connected to corresponding gate lines to output respective gate signals. The second output terminals OT2 of stages SRC1-SRCn output a carry signal.

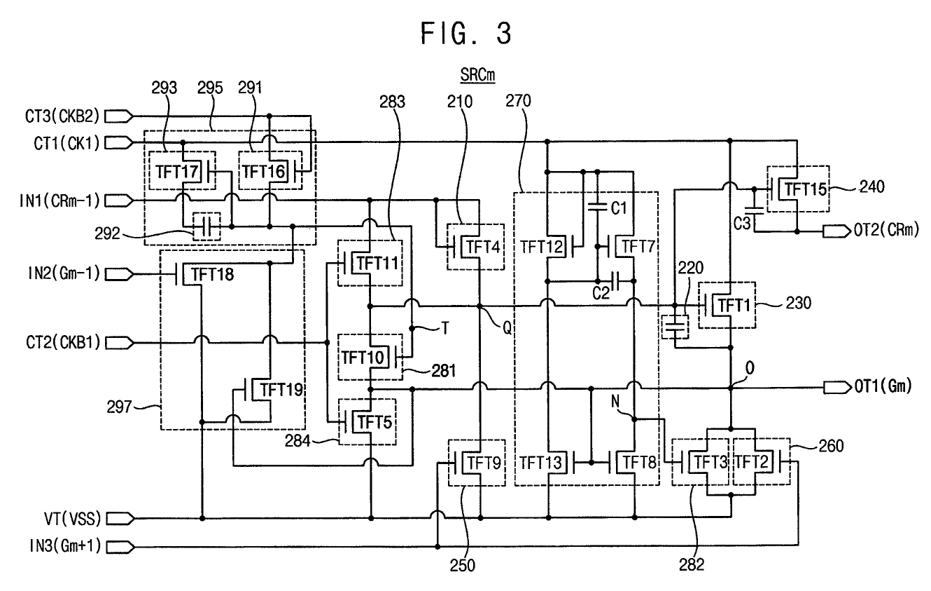

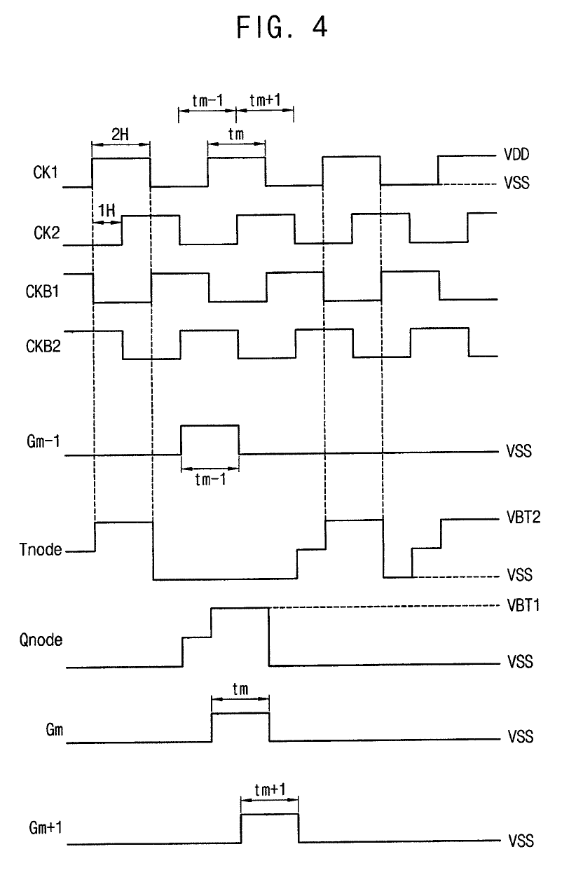

FIG. 3 is a circuit diagram illustrating a stage of FIG. 2, according to an exemplary embodiment of the present invention. FIG. 4 illustrates waveform diagrams showing exemplary input/output signals according to the gate drive circuit of FIG. 3.

Referring to FIGS. 2 and 3, an m-th stage SRCm includes a first buffer part 210, a first charging part 220, a pull-up part 230, a carry part 240, a discharging part 250, a pull-down part 260, a first switching part 270, a first maintenance part 281, a second maintenance part 282, a third maintenance part 283, a fourth maintenance part 284, a boost-up part 295, and a second switching part 297.

The first buffer part 210 includes a fourth transistor TFT4. A control part and an input part of the first buffer part 210 are connected to the first input terminal IN1, and an output part of the first buffer part 210 is connected to a first node Q. The first node Q is connected to an end of the first charging part 220. When a high voltage of an (m−1)-th carry signal CRm−1 of the previous stage is received by the first buffer part 210, the first charging part 200 charges to a first voltage V1 corresponding to the high voltage.

The pull-up buffer part 230 includes a first transistor TFT1. A control part of the pull-up part 230 is connected to the first node Q. An input part of the pull-up part 230 is connected to the first clock terminal CT1, and an output part of the pull-up part 230 is connected to an output node O. The control part of the pull-up part 230 is connected to one end of the first charging part 220, and the output node O is connected to the first output terminal OT1. One end of the first charging part 220 is connected to the first node Q, and the other end of the first charging part 220 is connected to the output node O.

While a first voltage V1 charged to the first charging part 220 is applied to the control part of the pull-up part 230, the pull-up part 230 is bootstrapped when the high voltage VDD of the first clock signal CK1 is received by the first clock terminal CT1. Here, the first node Q connected to the control part of the pull-up part 230 is boosted from the first voltage V1 to a boosted voltage VBT1. For example, the first voltage V1 is applied to the first node Q during an initial 1H in an (m−1)-th section tm−1, and the boosted voltage VBT1 is applied to the first node Q during an m-th section tm.

During the m-th section tm, in which the boosted voltage VBT1 is applied to the control part of the pull-up part 230, the pull-up part 230 outputs the high voltage of the first clock signal CK1 at the high voltage of the m-th gate signal Gm.

The carry part 240 includes a fifteenth transistor TFT15. A control part of the carry part 240 (e.g., the fifteenth transistor TFT15) is connected to the first node Q, an input part of the carry part 240 is connected to the first clock terminal CT1, and an output part of the carry part 240 is connected to the second output terminal OT2. In addition, the control part and the output part of the carry part 240 are connected to a first terminal and a second terminal of a third capacitor C3, respectively. When the high voltage is applied to the first node Q, the carry part 240 outputs the high voltage VDD of the first clock signal CK1 received by the first clock terminal in an m-th carry signal CRm.

The discharging part 250 includes a ninth transistor TFT9. A control part of the discharging part 250 (e.g., the ninth transistor TFT9) is connected to the third input terminal IN3, an input part of the discharging part 250 is connected to the first node Q and an output part of the discharging part 250 is connected to the voltage terminal VT. When an (m+1)-th gate signal Gm+1 is received by the third input terminal IN3, the discharging part 250 discharges the voltage of the first node Q at the low voltage VSS applied to the voltage terminal VT.

The pull-down part 260 includes a second transistor TFT2. A control part of the pull-down part 260 (e.g., the second transistor TFT2) is connected to the third input terminal IN3, an input part of the pull-down part 260 is connected to the output node O, and an output part of the pull-down part 260 is connected to the voltage terminal VT. When the (m+1)-th gate signal Gm+1 is received by the third input terminal IN3, the pull-down part 260 discharges the voltage of the output node O at the low voltage VSS.

The first switching part 270 includes a twelfth transistor TFT12, a seventh transistor TFT7, a thirteenth transistor TFT13 and an eighth transistor TFT8. A control part and an input part of the twelfth transistor TFT12 are connected to the first clock terminal CT1 and an output part of the twelfth transistor TFT12 is connected to an input part of the thirteenth transistor TFT13 and the seventh transistor TFT7. A control part and an input part of the seventh transistor TFT7 are connected to the first clock terminal CT1 and an output part of the seventh transistor TFT7 is connected to the third node N.

A control part of the thirteenth transistor TFT13 is connected to the output node O, an input part of the thirteenth transistor TFT13 is connected to the twelfth transistor TFT12, and an output part of the thirteenth transistor TFT13 is connected to the voltage terminal VT. A control part of the eighth transistor TFT8 is connected to the output node O, an input part of the eighth transistor TFT8 is connected to the third node N, and an output part of the eighth transistor TFT8 is connected to the voltage terminal VT.

The first switching part 270 discharges the first clock signal CK1 at the low voltage VSS applied to the voltage terminal VT, during an m-th section tm of a frame in which the high voltage is applied to the output node O. For example, the eighth transistor TFT8 and the thirteenth transistor TFT1 3 are turned on in response to the high voltage of the output node O, so that the high voltage of the first clock signal CK1 is discharged at the low voltage VSS.

In the first switching part 270, the eighth transistor TFT8 and the thirteenth transistor TFT13 are turned off during the other sections of the frame in which the low voltage is applied to the output node O, so that the first clock signal CK1 is applied to the third node N. For example, a first capacitor C1 and a second capacitor C2 may be further disposed in the first switching part 270. The first capacitor C1 may be electrically connected to a drain electrode and a gate electrode of the seventh transistor TFT7. The second capacitor C2 may be electrically connected to the gate electrode and a source electrode of the seventh transistor TFT7.

The first maintenance part 281 includes a tenth transistor TFT10. A control part of the first maintenance part 281 is connected to a second node T, an input part of the first maintenance part 281 is connected to the first node Q, and an output part of the first maintenance part 281 is connected to the output node O. The second node T is electrically connected to the first clock terminal CT1. The first maintenance part 281 shorts the first node Q and the output node O in response to the first clock signal CK1 during the other sections except for the m-th section tm of the frame, to maintain the first node Q and the output node O at the low voltage VSS.

The second maintenance part 282 includes a 3 rd transistor TFT3. A control part of the second maintenance part 282 is connected to the third node N, an input part of the second maintenance part 282 is connected to the output node O, and an output part of the second maintenance part 282 is connected to the voltage terminal VT. The second maintenance part 282 maintains the voltage of the output node O at the low voltage VSS in response to the first clock signal CK1, during the other sections of the frame.

The third maintenance part 283 includes an eleventh transistor TFT11. A control part of the third maintenance part 283 is connected to the second clock terminal CT2, an input part of the third maintenance part 283 is connected to the first input terminal IN1, and an output part of the third maintenance part 283 is connected to the first node Q. The third maintenance part 283 maintains the voltage of the first node Q at the low voltage of the (m−1)-th carry signal Crm−1, in response to the first inverted clock signal CKB1 received by the second clock terminal CT2 during the other sections of the frame.

The fourth maintenance part 284 includes a fifth transistor TFT5. A control part of the fourth maintenance part 284 is connected to the second clock terminal CT2, an input part of the fourth maintenance part 284 is connected to the output node O, and an output part of the fourth maintenance part 284 is connected to the voltage terminal VT. The fourth maintenance part 284 maintains the voltage of the voltage node O at the low voltage VSS, in response to the first inverted clock signal CKB1 during the other sections of the frame.

The boost-up part 295 boosts the voltage of the second node T to a certain level. Accordingly, the gate voltage boosted to have the high level is applied to the control part of the first maintenance part 281, thereby enabling a shift margin of a threshold voltage at high temperatures.

The boost-up part 295 includes a second buffer part 291, a second charging part 292 and a boosting part 293. The second buffer part 291 includes a sixteenth transistor TFT16. A control part and an input part of the second buffer part 291 are connected to the third terminal CT3 and an output part of the second buffer part 291 is connected to the second node T. The second charging part 292 includes a first terminal connected to the boosting part 293 and a second terminal connected the second node T. The boosting part 293 includes a control part connected to the second node T, an input part connected to the first clock terminal CT1, and an output part connected to the second terminal of the second charging part 292. The second charging part 292 may be a parasitic capacitor of the boosting part 293.

The second inverted clock signal CKB2, which is advanced (e.g., offset) by 1H with respect to a phase of the first clock signal CK1 received by the first clock terminal CT1, is received by the third clock terminal CT3. When the high voltage of the second inverted clock signal CKB2 is received, the second buffer part 291 is turned on to turn the boosting part 293 on. Here, in the second charging part 292, the voltage corresponding to the high voltage of the second inverted clock signal CKB2 is charged. Next, when the high voltage of the first clock signal CK1 is received, the boosting part 293 transmits the high voltage of the first clock signal CK1 to the second node T. Here, the second node T is bootstrapped through the second charging part 292 to have the boosted voltage VTB2. For example, when the high voltage of the first clock signal CK1 is about 27 V, the high voltage of the second node T that has been boosted may be above about 40 V.

The boost-up part 295 applies the boosted voltage VTB2 to the second node T (or the control part of the first maintenance part 291), in synchronization with the first clock signal CK1.

The second switching part 297 maintains the voltage of the second node T at the low voltage VSS during a period in which the first node Q has the high voltage. The second switching part 297 includes an eighteenth transistor TFT18 and a nineteenth transistor TFT19. A control part of the eighteenth transistor TFT18 is connected to the second input part IN2, an input part of the eighteenth transistor TFT18 is connected to the second node T, and an output part of the eighteenth transistor TFT18 is connected to the voltage terminal VT. A control part of the nineteenth transistor TFT19 is connected to the output node O, an input part of the nineteenth transistor TFT19 is connected to the second node T, and an output part of the nineteenth transistor TFT19 is connected to the voltage terminal VT.

The eighteenth transistor TFT18 maintains the voltage of the second node T at the low voltage VSS in response to the (m−1)-th gate signal Gm−1 received by the second input terminal IN2. The nineteenth transistor TFT19 maintains the voltage of the second node T at the low voltage VSS in response to the high voltage of the output node O.

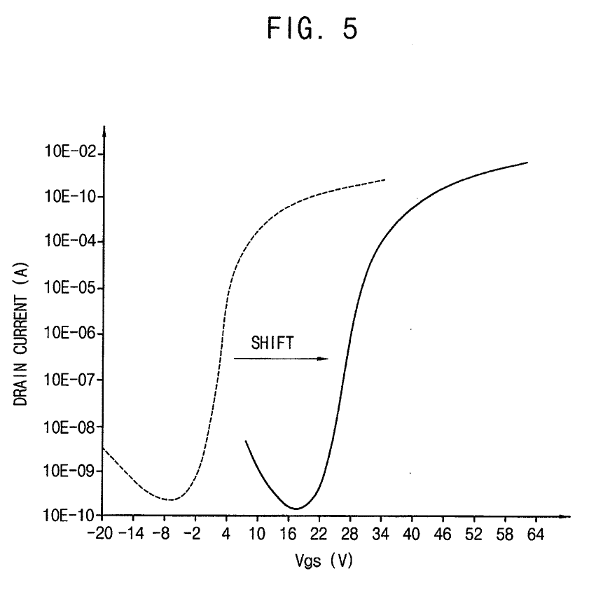

FIG. 5 is a concept diagram illustrating exemplary current-voltage characteristics of a first maintenance part of FIG. 3. Referring to FIGS. 3 and 5, the tenth transistor TFT10 of the first maintenance part 281 maintains the low voltage VSS of the m-th gate signal during the other sections of the frame.

When the tenth transistor 10 is driven for a long time, the threshold voltage Vth may be shifted. When the threshold voltage Vth is shifted, the gate voltage turning the tenth transistor TFT 10 on should also be increased to enable the tenth transistor TFT10 to be normally driven. However, the gate voltage is set to the high voltage of the first clock signal CK1, so that in the tenth transistor TFT10, a leakage current may be generated. At high temperatures, the tenth transistor TFT10 may not be normally driven, thereby not maintaining the low voltage VSS of the m-th gate signal during the other sections of the frame. Accordingly, high-temperature noise may be generated.

According to an exemplary embodiment of the invention, a gate voltage of the tenth transistor TFT10 of about 27 V may be boosted to above about 40 V through the boost-up part 295. In this example, since the gate voltage of the tenth transistor TFT10 is increased above 40 V, the tenth transistor TFT10 may be driven normally even though the threshold voltage Vth is shifted at the high temperature.

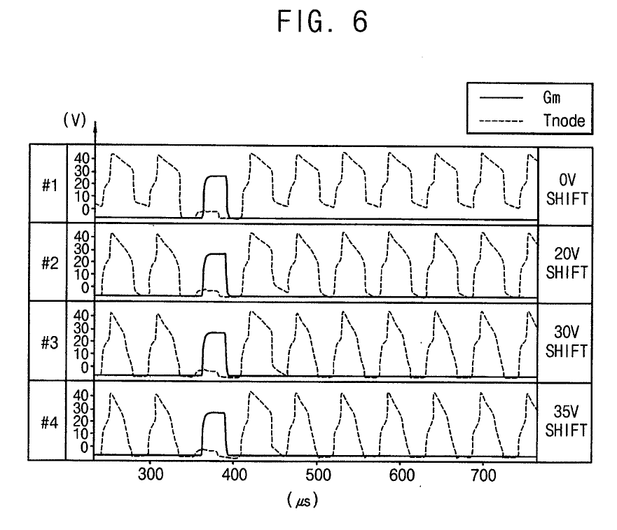

FIG. 6 are exemplary waveform diagrams showing a gate signal according to threshold voltages of the first maintenance part of FIG. 3. Referring to FIGS. 3 and 6, when the gate voltage of the first maintenance part 281 is increased by about 40 V using the boosted voltage VBT2, the waveform diagrams of the gate signal depending on the change of the threshold voltage Vth of the first maintenance part 281 are illustrated.

For example, sample #1 illustrates the gate signal Gm and the signal of the second node T measured when the threshold voltage Vth of the first maintenance part 281, e.g., the tenth transistor TFT 10 is shifted by 0 V. Sample #2 illustrates the gate signal Gm and the signal of the second node T measured when the threshold voltage Vth of the tenth transistor TFT 10 is shifted by 20 V. Sample #3 illustrates the gate signal Gm and the signal of the second node T measured when the threshold voltage Vth of the tenth transistor TFT 10 is shifted by 30 V. Sample #4 illustrates the gate signal Gm and the signal of the second node T measured when the threshold voltage Vth of the tenth transistor TFT 10 is shifted by 35 V.

As shown, the gate signal Gm is maintained at the low voltage in the other sections of the frame except for the m-th section tm of the frame maintained at the high voltage. As shown in FIG. 6, sample #1, sample #2, sample #3 and sample #4 may be almost constantly maintained at the low voltage without ripple noise during the other section of the frame.

As described above, in at least one embodiment of the present invention, the boosted voltage VBT2 may be about 40 V higher than the high voltage VDD of the first clock signal CK1, which is used as the gate voltage of the first maintenance part 281, thereby enabling the shifting margin of the threshold voltage Vth to be about 40 V.

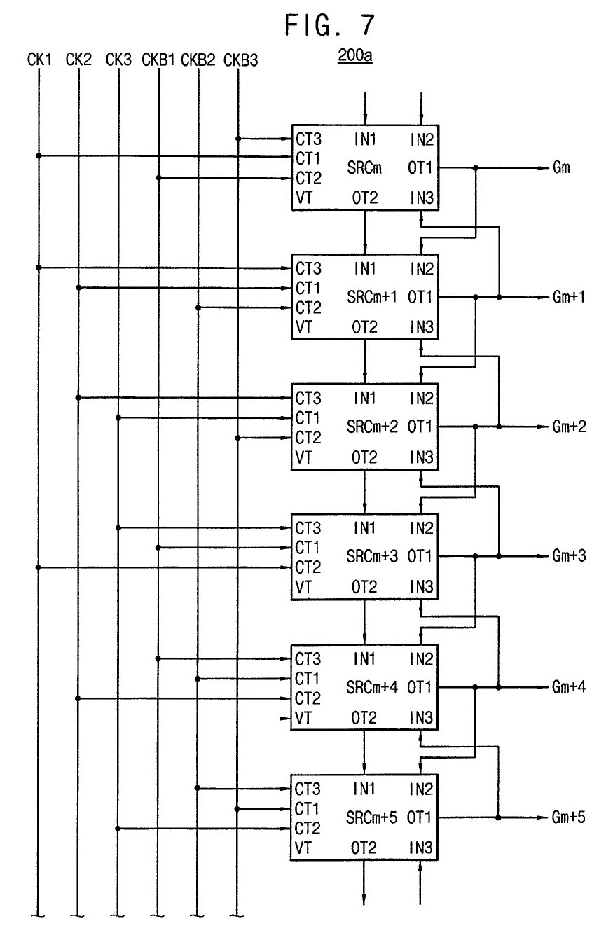

FIG. 7 is a block diagram illustrating a gate drive circuit according to exemplary embodiment of the present invention. Referring to FIGS. 1 and 7, the gate drive circuit 200a includes, dependently connected (e.g., cascade connected) stages such as a (6K-5)-th stage SRCm, a (6K-4)-th stage SRCm+1, a (6K-3)-th stage SRCm+2, a (6K-2)-th stage SRCm+3, a (6K-1)-th stage SRCm+4 and a 6K-th stage SRCm+5.

Each of the stages includes a first clock terminal CT1, a second clock terminal CT2, a third clock terminal CT3, a first input terminal IN1, a second input terminal IN3, a voltage terminal VT, a first output terminal OT1 and a second terminal OT2.

The first clock terminal CT1 receives a first clock signal CK1, a second clock signal CK2, a first inverted clock signal CKB1, a second inverted clock signal CKB2 or a third inverted clock signal CKB3. The clock signals CK1, CK2, CK3, CKB1, CKB2 or CKB3 include a high voltage VDD and a low voltage VSS, and have a pulse width of 3H and a period of 6H, where “H” is a horizontal period.

A phase of the second clock signal CK2 is delayed by 1H with respect to the phase of the first clock signal CK1. A phase of the third clock signal CK3 is delayed by 1H with respect to the phase of the second clock signal CK2. A phase of the first inverted clock signal CKB1 is inverted with respect to the phase of the first clock signal CK1, and is delayed by 1H with respect to the phase of the third clock signal CK3. The phase of the second inverted clock signal CKB2 is inverted with respect to the phase of the second clock signal CK2 and delayed by 1H with respect to the phase of the first inverted clock signal CKB1. The phase of the third inverted clock signal CKB3 is inverted with respect to the phase of the third clock signal CK3 and delayed by 1H with respect to the phase of the second inverted clock signal CKB2.

For example, the first clock terminal CT1 of the (6K-5)-th stage SRCm (K is a natural number) receives the first clock signal CK1, the first clock terminal CT1 of the (6K-4)-th stage SRCm+1 receives the second clock signal CK2, the first clock terminal CT1 of the (6K-3)-th stage SRCm+2 receives the third clock signal CK3, the first clock terminal CT1 of the (6K-2)-th stage SRCm+3 receives the first inverted clock signal CKB1, the first clock terminal CT1 of the (6K-1)-th stage SRCm+4 receives the second inverted clock signal CKB2, and the first clock terminal CT1 of the (6K)-th stage SRCm+5 receives the third inverted clock signal CKB3.

The second clock terminal CT2 receives a clock signal received by the first clock terminal CT1 and a clock signal having the inverted phase. For example, the second clock terminal CT2 of the (6K-5)-th stage SRCm (K is a natural number) receives the first inverted clock signal CKB1, the second clock terminal CT2 of the (6K-4)-th stage SRCm+1 receives the second inverted clock signal CKB2, the second clock terminal CT2 of the (6K-3)-th stage SRCm+2 receives the third inverted clock signal CKB3, the second clock terminal CT2 of the (6K-2)-th stage SRCm+3 receives the first clock signal CK1, the second clock terminal CT2 of the (6K-1)-th stage SRCm+4 receives the second clock signal CK2, and the second clock terminal CT2 of the (6K)-th stage SRCm+5 receives the third clock signal CK3.

The third clock terminal CT3 receives a clock signal that is offset from the clock signal received by the first clock terminal CT1. Namely, the phase of the clock signal received by the third clock terminal CT3 is delayed by 1H with respect to the clock signal received by the first clock terminal CT1.

For example, the third clock terminal CT3 of the (6K-5)-th stage SRCm (K is a natural number) receives the third inverted clock signal CKB3, the third clock terminal CT3 of the (6K-4)-th stage SRCm+1 receives the first clock signal CK1, the third clock terminal CT1 of the (6K-3)-th stage SRCm+2 receives the second clock signal CK2, the third clock terminal CT3 of the (6K-2)-th stage SRCm+3 receives the third clock signal CK3, the third clock terminal CT3 of the (6K-1)-th stage SRCm+4 receives the first inverted clock signal CKB1, and the third clock terminal CT3 of the (6K)-th stage SRCm+5 receives the second inverted clock signal CKB2.

The first input terminal IN1 receives a vertical start signal STV or a carry signal of a previous stage. For example, the first input terminal IN1 of a first stage SRC1 receives the vertical start signal STV and the first input terminal IN1 of the other stages receive a carry signal of a previous stage.

The second input terminal IN2 receives the vertical signal STV or a gate signal, e.g., an output signal of the previous stage. For example, the second input terminal IN2 of the first stage receives the vertical start signal STV and the second input terminal IN2 of the other stages receives the gate signal of the previous stage.

The third input terminal IN3 receives an output signal of a next stage or the vertical start signal STV. For example, the third input terminal IN3 of a last stage (e.g., a dummy stage) receives the vertical start signal STV corresponding to a next frame and the third input terminal IN3 of the other stages receives the gate signal of subsequent stage.

The voltage terminal VT receives the low voltage VSS. Each of the first output terminals OT1 is electrically connected to one of the gate lines to output a corresponding gate signal. The second output terminal OT2 outputs a carry signal.

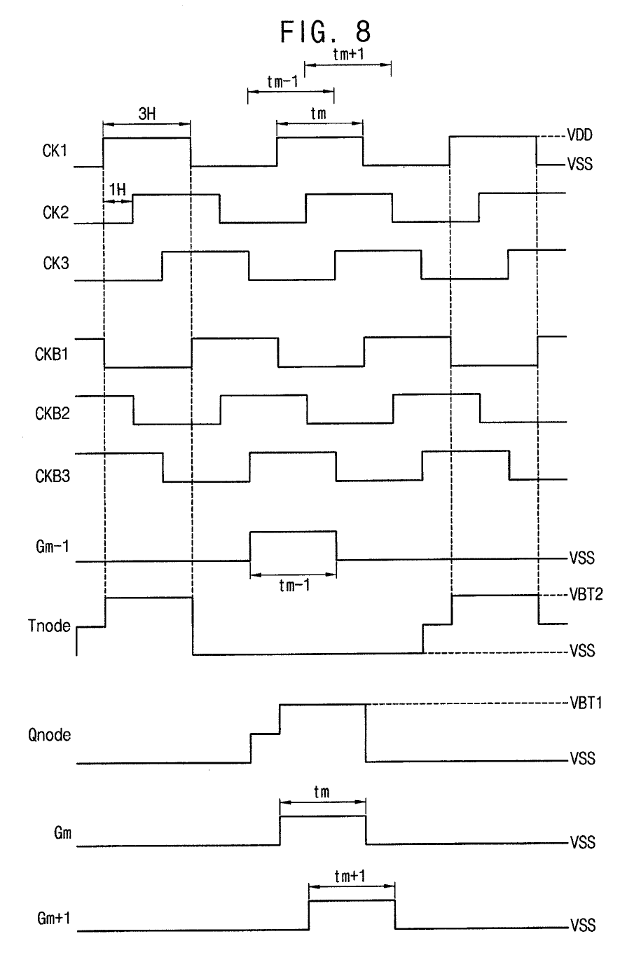

FIG. 8 are exemplary waveform diagrams showing input/output signals of the gate drive circuit of FIG. 7. Referring to FIGS. 3, 7, and 8, each of the stages (SRCm-SRCm+5) includes a first buffer part 210, a first charging part 220, a pull-up part 230, a carry part 240, a discharging part 250, a pull-down part 260, a first switching part 270, a first maintenance part 281, a second maintenance part 282, a third maintenance part 283, a fourth maintenance part 284, a boost-up part 295 and a second switching part 297.

Since each of the stages of FIG. 7 are substantially the same as the stages of FIG. 2, a detailed description of the above described components (e.g., 210, 220, 230, 240, 250, 260, 270, 281, 282, 283, 284, 294, 297, etc.) will be omitted. However, different from the stages of FIG. 2, some of the clock terminals of the stages of FIG. 7 receive additional clock signals CK3 and CKB3. For example, a clock signal received by a second buffer part 291 of the boost-up part 295 may differ from those described above.

For example, when the first clock signal CK1 is received by the first clock terminal CT1 and the first inverted clock signal CKB1 is received by the second clock terminal CT2, the third inverted clock signal CKB3 having a phase offset by 1H with respect to the phase of the first clock signal CK1 is received by the third clock terminal CT3. Accordingly, the second node T has a boosted voltage VSB2 synchronized to the first clock signal CK1. In addition, the voltage of the second node T is maintained at the low voltage VSS during a period in which the first node Q has the high voltage by the second switching part 297.

According to at least one exemplary embodiment of the present invention, a boosted voltage is applied to a control part of a first maintenance part, thereby obtaining a maximum shifting margin of a threshold voltage of the first maintenance part. Accordingly, high-temperature noise of the gate drive circuit generated by shifting of the threshold voltage of the first maintenance part may be removed.

Although exemplary embodiments of the present invention have been described, those skilled in the art will readily appreciate that various modifications can be made without departing from the spirit and scope of the present invention. Accordingly, all such modifications are intended to be included within the scope of the disclosure.

What is claimed is:

1. A gate drive circuit comprising:
a plurality of stages cascade connected to one another, each stage respectively outputting one of a plurality of gate signals, an m-th stage comprising:
a pull-up part outputting a high voltage of a first clock signal as a high voltage of an m-th gate signal in response to the high voltage of a first node;
a pull-down part applying a low voltage to an output node of the pull-up part in response to a high voltage of an (m+1)-th gate signal;
a boost-up part boosting-up a voltage charged by a second clock signal that has a phase that is offset from the first clock signal to apply the boosted voltage to a second node;
a first maintenance part maintaining a voltage potential of the first node at the low voltage in response to the boosted voltage of the second node; and
a second maintenance part maintaining the m-th gate signal at the low voltage in response to the high voltage of the first clock signal,
wherein m is a natural number.

2. The gate drive circuit of claim 1, further comprising:
a first switching part maintaining a voltage potential of a third node at the low voltage during a period in which the m-th gate signal is at the high voltage, and applying a high voltage to the third node during a period in which the m-th gate signal is at the low voltage.

3. The gate drive circuit of claim 2, wherein the first maintenance part maintains a voltage potential of the first node at the low voltage of the m-th gate signal in response to the boosted voltage of the second node, and
the second maintenance part maintains the m-th gate signal at the low voltage in response to the high voltage of the third node.

4. The gate drive circuit of claim 2, further comprising:
a third maintenance part maintaining a voltage potential of the first node at the low voltage of an (m−1)-th carry signal in response to the high voltage of an inverted clock signal having an inverted phase with respect to the first clock signal; and
a fourth maintenance part maintaining the m-th gate signal at the low voltage in response to the voltage of the inverted clock signal.

5. The gate drive circuit of claim 4, further comprising:
a second switching part maintaining a voltage potential of the second node at the low voltage during a period in which the first node is at the high voltage, and applying the high voltage to the second node during a period in which the first node is at the low voltage.

6. The gate drive circuit of claim 5, wherein the pull-up part comprises a control part connected to the first node, an input part connected to a first clock terminal receiving the first clock signal, and an output part connected to the output node outputting the m-th gate signal,
the pull-down part comprises a control part connected to a third input terminal receiving the (m+1)-th gate signal, an input part connected to the output node, and an output part connected to an output terminal receiving the low voltage,
the first maintenance part comprises a control part connected to the second node, an input part connected to the first node, and an output part connected to the output node, and
the second maintenance part comprises a control part connected to the third node, an input part connected to the output part, and an output part connected to the voltage terminal.

7. The gate drive circuit of claim 6, wherein
the third maintenance part comprises a control part connected to a second clock terminal receiving the inverted clock signal, an input part connected to the first node, and an output part connected to a first input terminal receiving the (m-1)-th carry signal, and
the fourth maintenance part comprises a control part connected to the second clock terminal, an input part connected to the output node, and an output part connected to the voltage terminal.

8. The gate drive circuit of claim 7, further comprising:
a first buffer part comprising a control part and an input part that are connected to the first input terminal, and an output part connected to the first node;
a first charging part comprising a first terminal connected to the first node, and a second terminal connected to the output node;
a discharging part comprising a control part connected to the third input part, an input part connected to the first node, and an output part connected to the voltage terminal; and
a carry part comprising a control part connected to the first node and an input part connected to the first clock terminal, the carry part outputting an m-th carry signal.

9. The gate drive circuit of claim 6, wherein the boost-up part comprises:
a second buffer part comprising a control part and an input part connected to a third clock terminal receiving the second clock signal and an output part connected to the second node;
a boosting part comprising a control part and an output part connected to the second node and an input part connected to the first clock terminal; and
a second charging part comprising a first terminal connected to the output part of the boosting part and a second terminal connected to the second node.

10. The gate drive circuit of claim 9, wherein the second switching part comprises:
a first transistor comprising a control part connected to a second input part receiving an (m−1)-th gate signal, an input part connected to the second node, and an output part connected to the voltage terminal; and
a second transistor comprising a control part connected to the output node, an input part connected to the second node, and an output part connected to the voltage terminal.

11. The gate drive circuit of claim 10, wherein the phase of the second clock signal is offset by one horizontal period with respect to the phase of the first clock signal.

12. A display apparatus comprising:
a display panel comprising a display area having a plurality of gate lines and a plurality of source lines and a peripheral area surrounding the display area, the display area configured to display an image;
a source drive circuit outputting a plurality of data signals to the source lines; and
a gate drive circuit integrated in the peripheral area, the gate drive circuit comprising a plurality of stages, each stage outputting one of a plurality of gate signals to
the gate lines, respectively, an m-th stage comprising:
a pull-up part outputting a high voltage of a first clock signal as a high voltage of an m-th gate signal in response to the high voltage of a first node;
a pull-down part applying a low voltage to an output node of the pull-up part in response to a high voltage of an (m+1)-th gate signal;
a boost-up part boosting-up a voltage charged by a second clock signal that has phase that is offset with respect to the first clock signal to apply the boosted voltage to a second node;
a first maintenance part maintaining a voltage potential of the first node at the low voltage in response to the boosted voltage of the second node; and
a second maintenance part maintaining the m-th gate signal at the low voltage in response to the high voltage of the first clock signal.

13. The display apparatus of claim 12, wherein the m-th stage further comprises:
a first switching part maintaining a voltage potential of a third node at the low voltage during a period in which the m-th gate signal is the high voltage and applying a high voltage to the third node during a period in which the m-th gate signal is the low voltage, and
the first maintenance part maintains a voltage potential of the first node to the m-th gate signal in response to the boosted voltage of the second node and maintains a voltage potential of the m-th gate signal at the low voltage in response to the high voltage of the third node.

14. The display apparatus of claim 13, wherein the m-th stage further comprises:
a third maintenance part maintaining a voltage potential of the first node at the low voltage of an (m−1)-th carry signal in response to the high voltage of an inverted clock signal having an inverted phase with respect to the phase of the first clock signal; and
a fourth maintenance part maintaining a voltage potential of the m-th gate signal at the low voltage in response to the high voltage of the inverted clock signal.

15. The display apparatus of claim 14, wherein the m-th stage further comprises:
a second switching part maintaining a voltage potential of the second node at the low voltage during a period in which the first node is at the high voltage and applying a high voltage to the second node during a period in which the first node is at the low voltage.

16. The display apparatus of claim 15, wherein the pull-up part comprises a control part connected to the first node, an input part connected to a first clock terminal receiving the clock signal, and an output part connected to the output node outputting the m-th gate signal,
the pull-down part comprises a control part connected to a third input terminal receiving the (m+1)-th gate signal, an input part connected to the output node and an output part connected to an output terminal receiving the low voltage,
the first maintenance part comprises a control part connected to the second node, an input part connected to the first node and an output part connected to the output node,
the second maintenance part comprises a control part connected to the third node, an input part connected to the output part and an output part connected to the voltage terminal,
the third maintenance part comprises a control part connected to a second clock terminal receiving the inverted clock signal, an input part connected to the first node, and an output part connected to a first input terminal receiving the (m−1)-th carry signal, and
the fourth maintenance part comprises a control part connected to the second clock terminal, an input part connected to the output node, and an output part connected to the voltage terminal.

17. The display apparatus of claim 16, further comprising:
a first buffer part comprising a control part and an input part that are connected to the first input terminal, and an output part connected to the first node;
a first charging part comprising a first terminal connected to the first node and a second terminal connected to the output node;
a discharging part comprising a control part connected to the third input part, an input part connected to the first node, and an output part connected to the voltage terminal; and
a carry part comprising a control part connected to the first node, and an input part connected to the first clock terminal, the carry part outputting an m-th carry signal.

18. The display apparatus of claim 16, wherein the boost-up part comprises:
a second buffer part comprising a control part and an input part that are connected to a third clock terminal receiving the second clock signal, and an output part connected to the second node;
a boosting part comprising a control part and an output part that are connected to the second node, and an input part connected to the first clock terminal; and
a second charging part comprising a first terminal connected to the output part of the boosting part, and a second terminal connected to the second node.

19. The display apparatus of claim 18, wherein the second switching part comprises:
a first transistor comprising a control part connected to a second input part receiving an (m−1)-th gate signal, an input part connected to the second node, and an output part connected to the voltage terminal; and
a second transistor comprising a control part connected to the output node, an input part connected to the second node, and an output part connected to the voltage terminal.

20. The display apparatus of claim 19, wherein the phase of the second clock signal is advanced by one horizontal period with respect to the phase of the first clock signal.
